(19) United States
(12) Patent Application Publication
(10) Pub. No.: US 2018/0226470 A1
(43) Pub. Date: Aug. 9, 2018

(54) METHOD OF FABRICATING BOTTOM ELECTRODE

(71) Applicants: UNITED MICROELECTRONICS CORP., Hsin-Chu City (TW); Fujian Jinhua Integrated Circuit Co., Ltd., Quanzhou City (CN)

(72) Inventors: Ger-Pin Lin, Tainan City (TW); Tien-Chen Chan, Tainan City (TW); Shu-Yen Chan, Changhua County (TW); Chi-Mao Hsu, Tainan City (TW); Shih-Fang Tzou, Tainan City (TW)

(21) Appl. No.: 15/873,913

(22) Filed: Jan. 18, 2018

(30) Foreign Application Priority Data
Feb. 3, 2017 (CN) 201710063727.8

(51) Int. Cl. H01L 49/02; H01L 27/108

(52) U.S. Cl. CPC H01L 28/84; H01L 27/10852; H01L 27/10808; H01L 28/90

(57) ABSTRACT

A method of fabricating a bottom electrode includes providing a dielectric layer. An atomic layer deposition is performed to form a bottom electrode material on the dielectric layer. Then, an oxidation process is performed to oxidize part of the bottom electrode material. The oxidized bottom electrode material transforms into an oxide layer. The bottom electrode material which is not oxidized becomes a bottom electrode. A top surface of the bottom electrode includes numerous hill-like profiles. Finally, the oxide layer is removed.

### BACKGROUND OF THE INVENTION

### 1. Field of the Invention

The present invention relates to a method of fabricating a bottom electrode, and more particularly to a method of fabricating a bottom electrode having numerous hill-like profiles

### 2. Description of the Prior Art

A typical dynamic random access memory (DRAM) cell includes a transistor and a capacitor. In early DRAM cells, planar type capacitors were used which require large wafer real estate. In recent years, as the size of IC devices is continuously miniaturized by smaller chips being made and more devices being packed into a chip, the circuit density on the a has increased to such an extent that the specific capacitance of a capacitor must be increased in order to meet the demand. Since the chip size is limited, the only feasible way of increasing the specific capacitance of a capacitor is to increase its electrode surface area.

The capacitor area is limited to the cell size, however, in order to accommodate the multitude of cells on the DRAM chip. It is therefore necessary to explore alternative methods for increasing the capacitance while decreasing the area occupied by the capacitor.

### SUMMARY OF THE INVENTION

A principal objective of the present invention is to increase the capacitance by increasing the surface area of the electrode.

According to a preferred embodiment of the present invention, a method of fabricating a bottom electrode includes providing a dielectric layer. First, an atomic layer deposition is performed to forma bottom electrode material on the dielectric layer. An oxidation process is performed to oxidize part of the bottom electrode material, wherein the part of the bottom electrode material which is oxidized is transformed into an oxide layer, while the part of the bottom electrode material which is not oxidized becomes a bottom electrode. A top surface of the bottom electrode includes numerous hill-like profiles. Finally, the oxide layer is removed.

According to a preferred embodiment of the present invention, after the bottom electrode is formed, a capacitor dielectric layer and a top electrode are formed in sequence to cover the bottom electrode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 depict a method of fabricating a bottom electrode of a capacitor according to a preferred embodiment of the present invention, wherein:

FIG. 1 depicts a dielectric layer with a trench therein;

FIG. 2 shows a magnified view of a region A in FIG. 1;

FIG. 3 is a fabricating stage following FIG. 1;

FIG. 4 depicts a magnified view of a region B in FIG. 3;

FIG. 5 is a fabricating stage following FIG. 3;

FIG. 6 depicts a magnified view of a region C in FIG. 5;

FIG. 7 is a fabricating stage following FIG. 5; and

FIG. 8 is a fabricating stage following FIG. 7.

FIG. 9 depicts a dynamic random access memory schematically.

### DETAILED DESCRIPTION

In the following description, numerous specific details are given to provide a thorough understanding of the invention. In order to focus on the specific inventive features of the present invention, some well-known system configurations and process steps are not disclosed in detail.

A method of fabricating a bottom electrode of a capacitor is provided in the present invention. The method of the present invention can be utilized to manufacture a bottom electrode of any type of capacitor such as a planar capacitor, a stacked capacitor or a trench capacitor. In the following embodiment, a stacked capacitor is illustrated as an example.

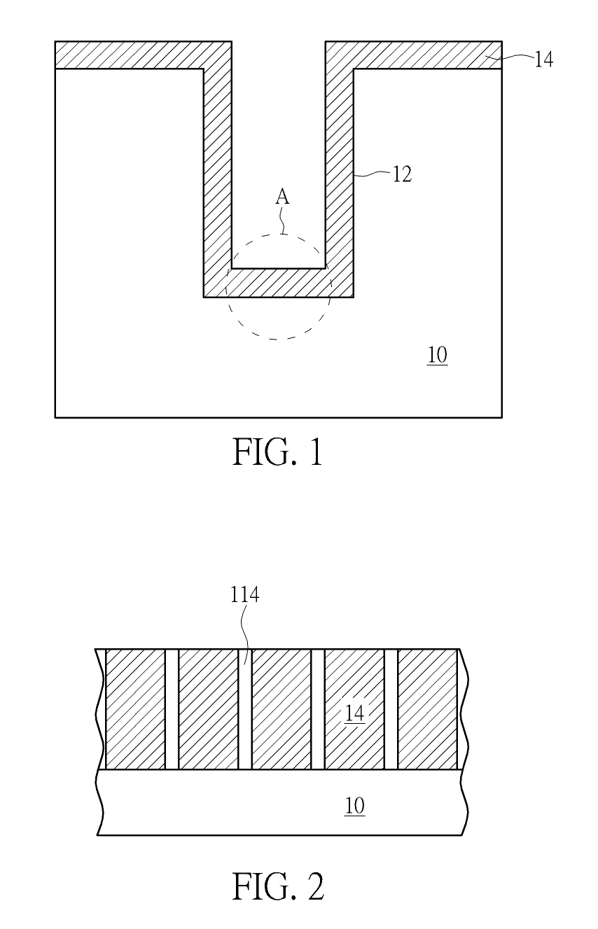

FIG. 1 to FIG. 8 depict a method of fabricating a bottom electrode of a capacitor according to a preferred embodiment of the present invention. As shown in FIG. 1, a dielectric layer 10 is provided. The dielectric layer 10 may be silicon nitride, silicon oxide, or silicon oxynitride. A trench 12 is disposed within the dielectric layer 10. Next, a bottom electrode material 14 is formed to conformally cover the trench 12 and a top surface of the dielectric layer 10. The bottom electrode material 14 includes titanium nitride, aluminum, copper, platinum, ruthenium oxide or tungsten. According to a preferred embodiment of the present invention, the bottom electrode material 14 is titanium nitride. The bottom electrode material 14 can be formed by a deposition process such as a chemical vapor deposition, a physical vapor deposition or an atomic layer deposition.

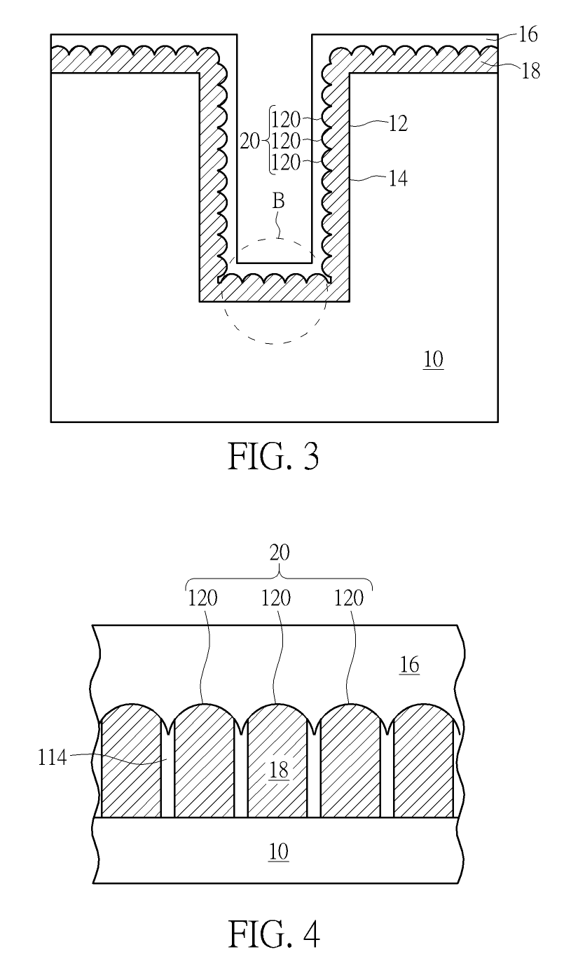

FIG. 2 shows a magnified view of a region A in FIG. 1. Please refer to both FIG. 1 and FIG. 2. According to a preferred embodiment of the present invention, the bottom electrode material 14 is formed by an atomic layer deposition process. Atomic layer deposition (ALD) is a thin-film deposition technique based on the sequential use of a gas phase chemical process. The majority of ALD reactions use a precursor reacting with the surface of a material in a sequential, self-limiting, manner. Through repeated exposure to the precursor, a thin film is slowly deposited. The atoms in the film are arranged repeatedly and regularly. Because the bottom electrode material 14 is formed by the atomic layer deposition, each of the grains in the bottom electrode material has a clear and repeated grain boundary 114. The grain boundary 114 is the interface between two adjacent grains. It should be noted that the top surface of the bottom electrode material 14 is flat at this stage.

Please refer to FIG. 1 and FIG. 3. An oxidation process is performed to oxidize part of the bottom electrode material. The oxidized bottom electrode material 14 is transformed into an oxide layer 16. The bottom electrode material 14 which is not oxidized becomes a bottom electrode 18. A top surface 20 of the bottom electrode 18 includes numerous hill-like profiles 120. Each of the hill-like profiles 120 is formed of a single grain. If the bottom capacitor material 14 is titanium nitride, the oxide layer 16 would be titanium oxide. The oxidation process may be a chemical oxidation process, a thermal oxidation process or other suitable oxidation processes. In detail, during the oxidation process, the top surface of the bottom electrode material 14 is oxidized by oxygen. Next, oxygen diffuses into the inner part of the bottom electrode material 14 along the grain boundary 114, and some of the inner part of the bottom electrode material 14 is oxidized and transformed into the oxide layer 16. The part of the bottom electrode material 14 which is not oxidized is defined as a bottom electrode 18. When the oxygen diffuses along the grain boundary 114 to oxidize the bottom electrode material 14, the top surface of the bottom electrode material 14 which is not oxidized forms numerous hill-like profiles 120. In other words, the top surface 20 of the bottom electrode 18 has numerous hill-like profiles 120. FIG. 4 depicts a magnified view of a region B in FIG. 3. As shown in FIG. 4, the top surface 20 of each of the hill-like profiles 120 connects to each other.

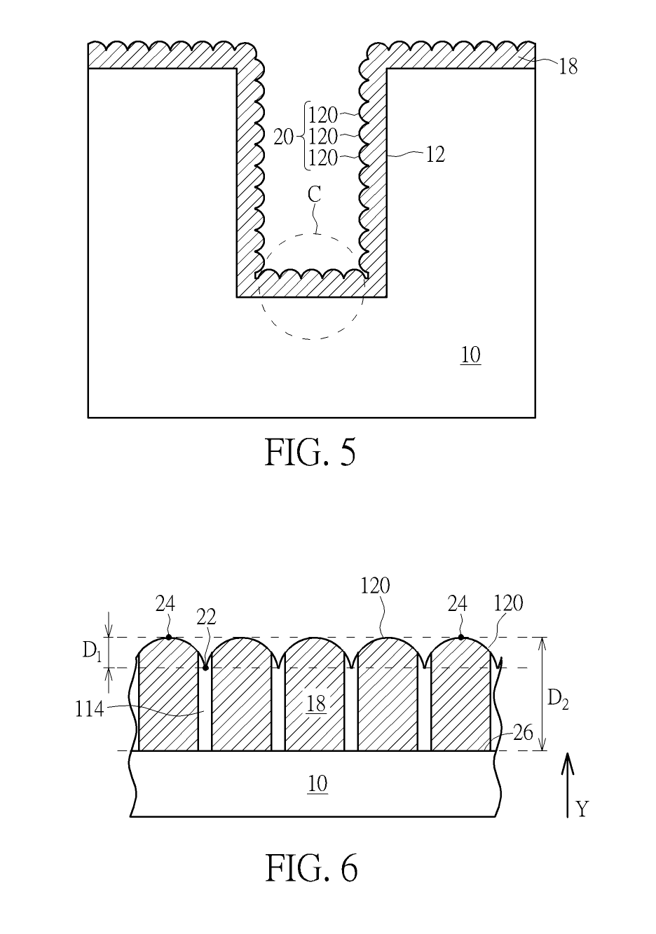

As shown in FIG. 5, the oxide layer 16 is removed and the bottom electrode 18 is exposed. The oxide layer 16 may be removed by a wet etching, a dry etching, or a reactive ion etching. At this point, the bottom electrode 18 is completed. FIG. 6 depicts a magnified view of a region C in FIG. 5. As shown in FIG. 6, according to a preferred embodiment of the present invention, the sizes of each of the hill-like profiles 120 are the same, but the invention is not limited thereto. After adjusting manufacturing parameters, the sizes of each of the hill-like profiles 120 can be different. Under the circumstance that the size of each of the hill-like profiles 120 is the same, a lowest point 22 is disposed between adjacent hill-like profiles 120. Furthermore, each of the hill-like profiles 120 includes a highest point 24. A first distance D₁ is defined between the lowest point 22 and the highest point 24 along a vertical direction Y. A bottom side 26 of the bottom electrode 18 contacts the dielectric layer 10. A second distance D₂ is defined between the bottom side 26 and the highest point 24 along the vertical direction Y. A ratio of the first distance D₁ to the second distance D₂ is between 0.05 and 0.9. The vertical direction Y is defined as a direction which is perpendicular to a top surface of the dielectric layer 10. Moreover, the bottom electrode material 14 may be titanium nitride, aluminum, copper, platinum, ruthenium oxide, tungsten or other conductive material. The bottom electrode 18 formed from the bottom electrode material 14 may also include titanium nitride, aluminum, copper, platinum, ruthenium oxide, tungsten or other conductive material. The bottom electrode 18 is preferably titanium nitride. It is noteworthy that the top surface of the bottom electrode material 14 is flat when the bottom electrode material 14 is just formed. After the oxidation process is finished, the hill-like profiles 120 are formed. In other words, the hill-like profiles 120 are formed due to the oxidation process.

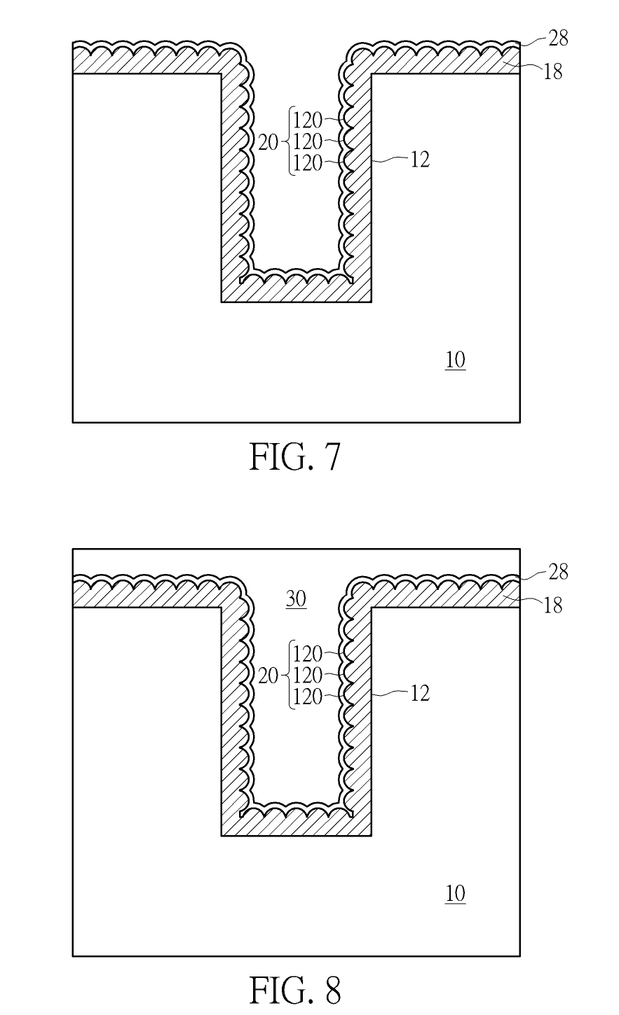

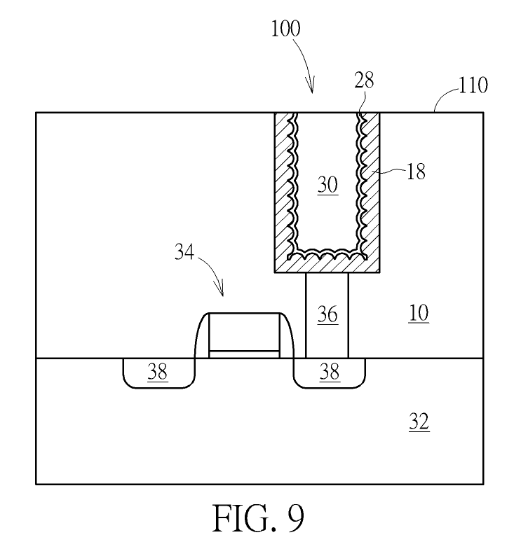

As shown in FIG. 7, a capacitor dielectric layer 28 is formed to conformally cover the bottom electrode 18. The capacitor dielectric layer 28 may be high-k dielectrics such as Al₂O₃ , ZrO₂, barium strontium titanate (BST), lead zirconate titanate (PZT), ZrSiO₂, HfSiO₂, HfSiON, TaO₂, and the like. As shown in FIG. 8, a top electrode 30 is formed to cover the capacitor dielectric layer 28. As shown in FIG. 9, the top electrode 30, the capacitor dielectric layer 28 and the bottom electrode 18 are etched back to remove the top electrode 30, and the capacitor dielectric layer 28 and the bottom electrode 18 cover the top surface 110 of the dielectric layer 10. At this point, a capacitor 100 is completed.

According to a preferred embodiment of the present invention, a substrate 32 is disposed below the dielectric layer 10. The substrate 32 may be a bulk silicon substrate, a germanium substrate, a gallium arsenide substrate, a silicon germanium substrate, an indium phosphide substrate, a gallium nitride substrate, or a silicon carbide substrate. A transistor 34 may be disposed on the substrate 32. The capacitor 100 may electrically connect to the transistor 34 to form a dynamic random access memory (DRAM). The bottom electrode 18 electrically connects to a capacitor plug 36. The capacitor plug 36 electrically connects to one of the source/drain doping regions 38.

The capacitance of a capacitor relates to the surface area of the top electrode and the bottom electrode and the distance between the top electrode and the bottom electrode. The surface area of the bottom electrode of the present invention is increased by oxidizing the bottom electrode material to form numerous hill-like profiles. Therefore, the capacitance can be raised.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating a bottom electrode, comprising:
providing a first dielectric layer;
performing an atomic layer deposition to form a bottom electrode material on the dielectric layer;
performing an oxidation process to oxidize part of the bottom electrode material, wherein a part of the bottom electrode material which is oxidized is transformed into an oxide layer, a part of the bottom electrode material which is not oxidized becomes a bottom electrode, and a top surface of the bottom electrode comprises a plurality of hill-like profiles; and
removing the oxide layer.

2. The method of fabricating a bottom electrode of claim 1, further comprising:
forming a capacitor dielectric layer to cover the bottom electrode; and
forming a top electrode to cover the capacitor dielectric layer.

3. The method of fabricating a bottom electrode of claim 2, wherein
the capacitor dielectric layer is formed after the oxide layer is removed completely.

4. The method of fabricating a bottom electrode of claim 1, wherein
the bottom electrode material comprises titanium nitride, aluminum, copper, platinum, ruthenium oxide or tungsten.

5. The method of fabricating a bottom electrode of claim 1, wherein
the dielectric layer contacts a bottom side of the bottom electrode.

6. The method of fabricating a bottom electrode of claim 5, wherein
the plurality of hill-like profiles connect to each other and each of the hill-like profiles is of the same size.

7. The method of fabricating a bottom electrode of claim 6, wherein a lowest point is disposed between the hill-like profiles adjacent to each other, each of the hill-like profiles comprises a highest point, a first distance is defined between the lowest point and the highest point along a vertical direction, a second distance is defined between the bottom side and the highest point along the vertical direction, and a ratio of the first distance to the second distance is between 0.05 and 0.9.
